(19) United States
(12) Patent Application Publication
(10) Pub. No.: US 2013/0249293 A1
(43) Pub. Date: Sep. 26, 2013

(54) FUNCTIONAL BACK GLASS FOR A SOLAR PANEL

(71) Applicants: Fan Yang, Sunnyvale, CA (US); Gaurav Sethi, Dublin, CA (US); Evgeni Petrovich Gousev, Saratoga, CA (US); Patrick Forrest Brinkley, San Mateo, CA (US); Ravindra V. Shenoy, Dublin, CA (US); Sijin Han, Milpitas, CA (US)

(72) Inventors: Fan Yang, Sunnyvale, CA (US); Gaurav Sethi, Dublin, CA (US); Evgeni Petrovich Gousev, Saratoga, CA (US); Patrick Forrest Brinkley, San Mateo, CA (US); Ravindra V. Shenoy, Dublin, CA (US); Sijin Han, Milpitas, CA (US)

(73) Assignee: QUALCOMM MEMS TECHNOLOGIES, INC., San Diego, CA (US)

(21) Appl. No.: 13/430,533

(22) Filed: Mar. 26, 2012

(51) Int. Cl. H02J 1/10; H01L 31/18; H02M 7/5387

(52) U.S. Cl. 307/43; 363/132; 438/64; 257/E31.117

(57) ABSTRACT

A photovoltaic solar panel includes a front glass, a back glass, and a photovoltaic (PV) power generating layer encapsulated between the front glass and the back glass. The PV power generating layer is configured to convert ambient electromagnetic energy, received through the front glass, to a direct current (DC) power output. The PV solar panel also includes at least one component, disposed behind the PV power generating layer, selected from the group consisting of: a direct current to alternating current (DC-AC) inverter configured to convert the DC power output from the PV power generator to an alternating current (AC) power output, a battery, and an antenna.

### TECHNICAL FIELD

This disclosure relates to photovoltaic solar panels, and, more specifically, to a solar panel having a functional back glass.

### DESCRIPTION OF THE RELATED TECHNOLOGY

A conventional photovoltaic solar panel, whether having crystalline or thin film photovoltaic (PV) power generators, includes a PV power generating layer sandwiched between a transparent front substrate and a back substrate. Each of the substrates, commonly, is made of glass, and the terms “front glass” and “back glass” may be used to refer to these components. Ambient electromagnetic energy from, e.g., sunlight, is received at the PV power generating layer through the transparent front glass. A junction box is typically disposed on the back side of the back glass for interconnecting the solar panel to an adjacent solar panel and/or to a power bus. The back glass, which may be secured to the front glass with an epoxy, functions primarily as a mechanical component that, for example, prevents intrusion of moisture into the interior of the “sandwich”, provides mechanical rigidity of the assembled solar panel, and an attachment area for the junction box.

When integrated into an array, such solar panels are typically connected in a series string and deliver direct current (DC) output power thereto. The series string typically also includes, for example, a DC disconnect, an inverter for converting DC current to alternating current (AC), an AC disconnect, and a power meter. Such components are typically disposed externally to any individual solar panel. Alternatively, some such components may be disposed in the interior of a panel “sandwich” by displacing or covering part of the PV power generating layer.

As a result, undesirably, the above-described techniques entail a complex and expensive integration of components external to the solar panels, do not permit monitoring and control of an individual solar panel, and/or reduce the effective area of the PV power generating layer.

### SUMMARY

The systems, methods and devices of the disclosure each have several innovative aspects, no single one of which is solely responsible for the desirable attributes disclosed herein. One innovative aspect of the subject matter described in this disclosure can be implemented in a PV solar panel having a front glass, a back glass, and a PV power generating layer encapsulated between the front glass and the back glass. The PV power generating layer may include, for example, a planar array of crystalline solar cells, or a thin film PV layer. The PV power generating layer is configured to convert ambient electromagnetic energy, received through the front glass, to a direct current (DC) power output. The PV solar panel also includes at least one component, the at least one component including one or more of: a direct current to alternating current (DC-AC) inverter configured to convert the DC power output from the PV power generating layer to an AC power output, a battery, and an antenna. The at least one component is disposed behind the PV power generating layer.

In some implementations, the at least one component may be disposed on a surface of the back glass. The at least one component may be disposed on a front surface of the back glass, and encapsulated between the back glass and the PV power generating layer or may be disposed behind the back glass.

The DC-AC inverter may include a capacitor and an inductor; and one or both of the capacitor and the inductor are fabricated on the back glass. The back glass may be configured as a substrate for growing the capacitor and for deposition of the inductor. The DC-AC inverter may include a switching arrangement, a power transformer, a rectifier, a low pass filter and a resonator circuit.

In an implementation, the at least one component includes the battery, the battery being a thin form factor rechargeable battery having a thickness of less than approximately 10 millimeters.

In a further implementation, the at least one component includes the antenna and a radio frequency (RF) circuit, the antenna being a Zigbee or radio frequency identification (RFID) antenna.

The solar panel may include the DC-AC inverter, a logic control circuit, the antenna, and an RF circuit. Each of the DC-AC inverter, the logic control circuit, the battery, the antenna, and the RF circuit may be integrated as a module disposed behind the back glass. The solar panel may include one or more of: a sunlight photodetector, a temperature sensor, and wind velocity sensor. The antenna may be communicatively coupled to an array control center, and may transmit output data received from the logic control circuit or the at least one sensor to the array control center. The antenna may receive control signals from the array control center.

In some implementations a solar panel array includes a plurality of solar panels, connected in a string, each solar panel configured to produce an output power, and each solar panel including: a photovoltaic (PV) power generating layer encapsulated between the front glass and the back glass. Each solar panel includes a direct current to alternating current (DC-AC) inverter disposed behind a back surface of the PV generating layer; and the output power of each solar panel onto the string is only AC. The plurality of solar panels may be connected to the string in parallel. At least one solar panel may include an antenna that is communicatively coupled to an array control center. The at least one solar panel is configured to be monitored and controlled by the array control center, independent of any other solar panel in the solar panel array.

In an implementation, a photovoltaic (PV) solar panel includes a front glass, a first back glass, a second back glass, and a PV power generating layer encapsulated between the front glass and the first back glass. The second back glass is disposed behind the first back glass and includes one or more of: a direct current to alternating current (DC-AC) inverter, a battery, and an antenna. The second back glass may be laminated to the back surface of the first back glass.

In another implementation an apparatus includes means for generating photovoltaic (PV) power, encapsulated between a front glass and a back glass of a PV solar panel, and having a back surface, the PV solar panel defining a planar area; means, disposed behind the back surface and proximate to the center of the planar area, for converting direct current (DC) power to alternating current (AC) power. The means for converting DC power to AC power may be disposed on a surface of the back glass. The means for converting DC power to AC power may include at least one capacitor and at least one inductor, and wherein one or more of the capacitor and the inductor are fabricated on the back glass.

In a further implementation, a method for fabricating a photovoltaic (PV) solar panel includes disposing, on a surface of a back glass of the PV solar panel, one or more of: a direct current to alternating current (DC-AC) inverter, a battery, and an antenna; and encapsulating a photovoltaic power generating layer between a front glass of the PV solar panel and the back glass. The at least one component is disposed behind the PV power generating layer. The at least one component may be disposed on a front surface of the back glass, and encapsulated between the back glass and the PV power generating layer. The DC-AC inverter may include at least one capacitor and at least one inductor, and one or more of the capacitor and the inductor may be fabricated on the back glass.

In another implementation, a method includes monitoring signals from at least one individual photovoltaic (PV) solar panel of a solar panel array, the signals being received from an antenna disposed on the individual PV solar panel; controlling one or both of the individual PV solar panel and the solar panel array, responsive to the received signals. The individual PV solar panel includes a front glass, a back glass, and a PV power generating layer encapsulated between the front glass and the back glass and the antenna is disposed behind the PV power generating layer.

The solar panel array may include a plurality of solar panels, and the output power output of each solar panel in the array may include only AC power. The controlling one or both of the individual PV solar panel and the solar panel array may be performed at an array control center remote from the solar panel array, independent of any other solar panel in the solar panel array.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1A shows an example of an array of photovoltaic (PV) solar panels in accordance with an implementation.

FIG. 1B shows an example of an exploded perspective view of an example of a PV solar panel in accordance with an implementation.

FIG. 2 shows an example of a cross sectional elevation view of an example of a PV solar panel in accordance with an implementation.

FIG. 3 shows an example of a PV solar panel in accordance with a further implementation.

FIG. 4 shows an example of a PV solar panel in accordance with a further implementation.

FIG. 5 shows an example of a PV solar panel in accordance with a further implementation.

FIG. 6 shows an example of a block diagram of a DC-AC inverter.

FIG. 7A shows an example of a first intermediate result of a process to form a capacitor from a stacked layered structure.

FIG. 7B shows an example of a second intermediate result of a process to form a capacitor from a stacked layered structure.

FIG. 7C shows an example of a third intermediate result of a process to form a capacitor from a stacked layered structure.

FIG. 7D shows an example of a side view of a capacitor formed from a stacked layered structure.

FIG. 8 shows an example of a flow diagram illustrating a process for forming a capacitor from a stacked layered structure.

FIG. 9A shows an example of a first intermediate result of a process to form an inductor having a stacked layered structure serving as a magnetic core.

FIG. 9B shows an example of a perspective view of an inductor having a stacked layered structure serving as a magnetic core.

FIG. 10 shows an example of a flow diagram illustrating a method for forming an inductor as a MEMS device including a stacked layered structure.

FIG. 11 shows an example of a flow diagram illustrating a method of forming an inductor by depositing coil portions around a stacked layered structure.

FIGS. 12A-12E show an example of a top view of an inductor at respective stages of fabrication.

FIGS. 13A-13E show an example of a cross-sectional view along lines 13-13 of FIG. 12A of the inductor of FIGS. 12A-12E at the respective stages of fabrication.

FIG. 14 shows an example of a system including an array of photovoltaic (PV) solar panels with functional back glasses.

FIG. 15 shows an example of a flow diagram illustrating a method for fabricating a PV solar panel in accordance with an implementation.

FIG. 16 shows an example of a flow diagram illustrating a method for operating an array of PV solar panels in accordance with an implementation.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. Thus, the teachings are not intended to be limited to the implementations depicted solely in the Figures, but instead have wide applicability as will be readily apparent to one having ordinary skill in the art.

Described herein below are new techniques incorporating a photovoltaic (PV) solar panel having a front glass, a back glass, and a PV power generating layer encapsulated between the front glass and the back glass. One or more of a direct current to alternating current (DC-AC) inverter, a battery, and an antenna, is disposed behind the PV power generating layer. In some implementations, at least some components of the DC-AC inverter, the battery, and/or the antenna are disposed on a front surface of the back glass, encapsulated between the back glass and the PV power generator.

Particular implementations of the subject matter described in this disclosure can be implemented to realize one or more of the following potential advantages. By adding functionality to the back glass of a solar panel, in accordance with the present teachings, installation of an array of such solar panels is greatly simplified, while maintenance and other life cycle costs are significantly reduced. For example, when the DC-AC inverter, which may be configured as an integrated micro-inverter, is disposed in each solar panel behind the PV power generating layer, as described herein, each solar panel may deliver AC power, in parallel, to a string of solar panels or to an electrical grid. A need for external components such as an array inverter, and inverter disconnects, is thus avoided. Advantageously, because the DC-AC inverter is disposed behind the PV power generating layer, the entire planar area of the panel may be populated with PV power generating elements (e.g., solar cells, or an active PV thin film layer), without reserving part of the planar area for non-power generating components.

In addition, the present inventors have appreciated that an integrated solar panel, including a “functional back glass”, may enable simpler, less costly, system integration, while providing opportunities for more robust and granular array management and maintenance. As used herein, “functional back glass” broadly refers to a solar panel back glass that, in addition to the mechanical functionality of the prior art, includes, or has disposed thereon, one or more of a DC-AC inverter, a battery, and an antenna. In some implementations, the integrated solar panel of the presently disclosed techniques has substantially identical envelope dimensions, and mechanical interfaces as solar panels of the prior art. As noted above, the DC-AC inverter, the battery, the antenna, diagnostic and/or telecommunication components may be disposed in each solar panel, behind the PV power generating layer, thereby providing additional functionality without reducing the planar area available for the PV power generating layer. In some implementations, in-situ monitoring and diagnosis is facilitated by use of sensors and wireless communications components. In some implementations, the battery may be configured to locally store excess energy generated by the solar panel.

An array of solar panels configured along the lines of the present teachings provides a number of advantages with respect to the known art, particularly where a large array of solar panels is contemplated. For example, each solar panel may be configured to automatically monitor, and transmit, to an array control center, its PV energy conversion status, and/or automatically warn of a need for preventative maintenance when it senses potentially hazardous environmental conditions, such as extreme temperature or wind speed.

According to one innovative aspect of the subject matter described in this disclosure, a PV solar panel includes a front glass, a back glass, and a PV power generating layer encapsulated between the front glass and the back glass. The PV solar panel also includes one or more of the following components, disposed behind the PV power generating layer: a DC-AC inverter, a battery, and an antenna.

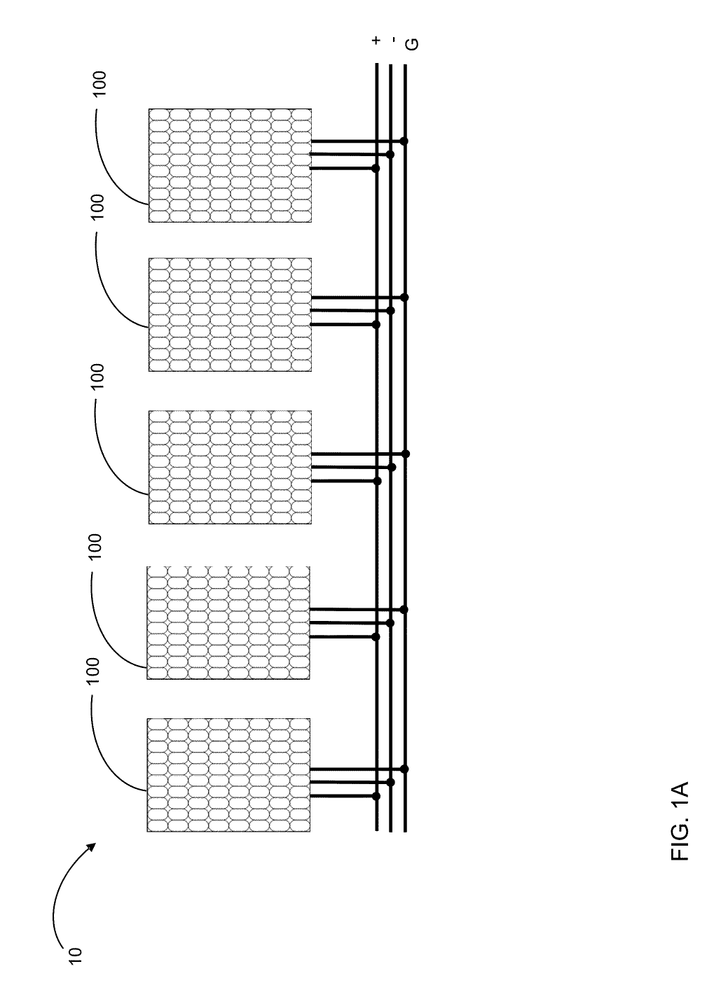

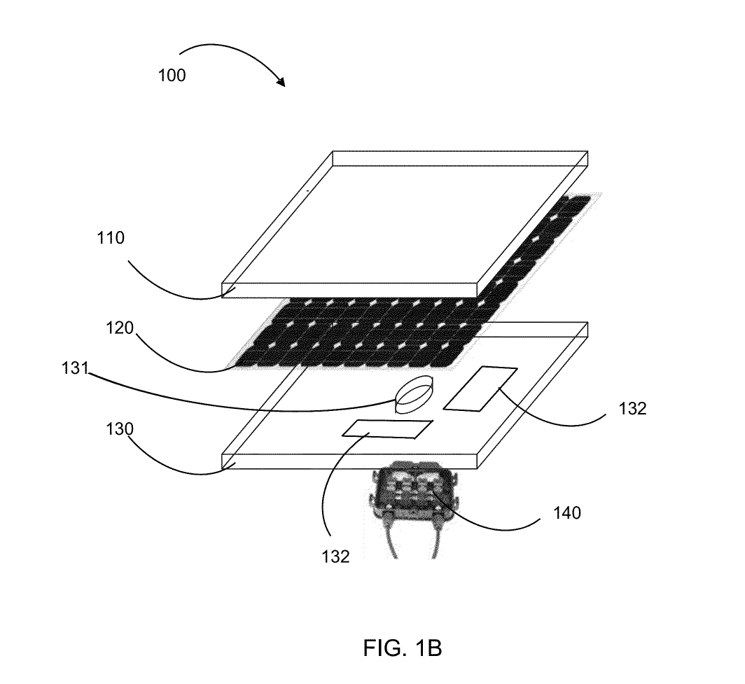

FIG. 1A shows an example of an array of photovoltaic (PV) solar panels in accordance with an implementation. According to the illustrated implementation, solar panel array 10 (also referred to as a “string”) of five solar panels 100. Advantageously, each solar panel 100 may include its own DC-AC inverter (not shown) and may be connected to the string in parallel. It will be understood that, although five solar panels 100 are illustrated, solar panel array 10 may include a smaller or greater number of solar panels 100. In some implementations, for example, solar panel array 10 may include many hundreds of solar panels 100. In some implementations described in more detail herein below, solar panel array 10, and/or individual solar panels 100 may be communicatively coupled to an array control center (not shown) that is configured to monitor and control operation of solar panel array 10.

FIG. 1B shows an example of an exploded perspective view of an example of a PV solar panel in accordance with an implementation. As illustrated, PV solar panel 100 includes front glass 110 and back glass 130. “Sandwiched” there between is PV power generating layer 120. PV power generating layer 120 may include, for example, a planar array of crystalline solar cells, or a thin film PV layer. When assembled, PV solar panel 100 may be configured such that PV power generating layer 120 is encapsulated between front glass 110 and back glass 130. The assembled PV solar panel 100 may include an epoxy system (not shown), such as an ethylene vinyl acetate (EVA) epoxy system, for joining PV power generating layer 120, front glass 110 and back glass 130, and for reducing or preventing intrusion of moisture and contamination into the assembled PV solar panel 100. Front glass 110 may be made of glass or any other suitable, substantially transparent, material, such as a plastic or a carbon phenolic composite material. Similarly, back glass 130 may be made of glass or any suitable material, such as a plastic or a carbon phenolic composite material. PV power generating layer 120 is configured to convert ambient electromagnetic energy, e.g., solar energy, received through front glass 110, to a direct current (DC) power output.

In some implementations, back glass 130 may include an access hole (“opening”) 131 through which electrical wiring from, for example, PV power generating layer 120 may be passed. Opening 131 may be located, as illustrated, proximate to a substantially central portion of a planar area defined by the perimeter of back glass 130. Enclosure 140 may be disposed proximate to opening 131, on the back side of back glass 130. Enclosure 140 may have similar functionality and external dimensions as the aforementioned conventional junction box. In addition, enclosure 140 may house one or more additional electrical components or elements. For example, one or more of a DC-AC inverter configured to convert the DC power output from the PV power generating layer 120 to an AC power output, a battery, and an antenna, may be disposed within enclosure 140.

Back glass 130, advantageously, may be provided with one or more regions 132 within which electrical elements may be disposed and/or fabricated as described herein below. Each region 132 may be proximate to the front side or the back side of back glass 130. Region 132 may, as illustrated, be proximate to opening 131.

Advantageously, in some implementations at least parts of the DC-AC inverter, the battery, and the antenna may be fabricated on, or disposed proximate to, an inner surface of the back glass. In some implementations, by selecting appropriate thin form components, the thickness of the panel “sandwich” for such implementations may be negligibly larger, or substantially the same as, the prior art. In some implementations the aforementioned components may be encapsulated together “inside the sandwich,” with the result that excellent environmental tolerance and longer system lifetime may be provided.

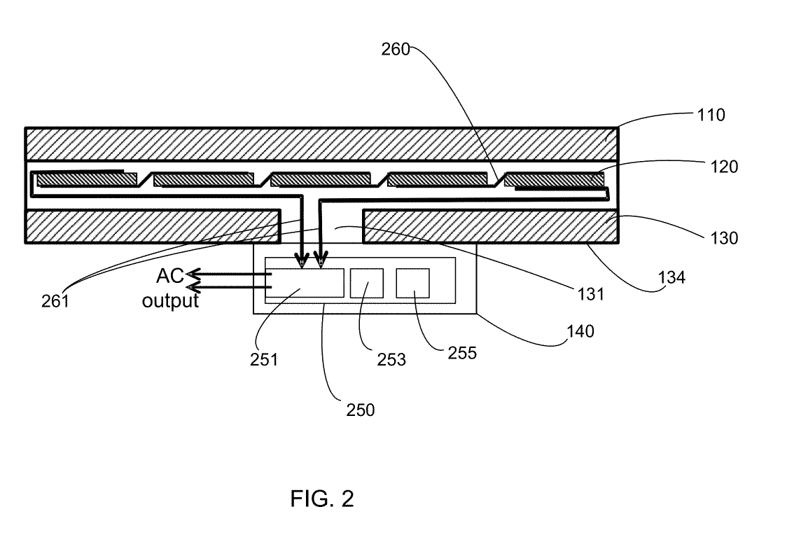

FIG. 2 shows an example of a cross sectional elevation view of an example of a PV solar panel in accordance with an implementation. As described above, front glass 110 and back glass 130 encapsulate PV power generating layer 120. In the illustrated implementation, PV power generating layer 120 is depicted as an array of crystalline solar cells, connected in series by bus wires 260. It will be appreciated, however, that PV power generating layer 120 may, alternatively, be a thin film PV layer or other arrangement operable to generate DC power from ambient electromagnetic energy. In the illustrated implementation, interconnect wires 261 for conducting DC power from PV power generating layer 120 to DC-AC inverter 251 are routed through opening 131. DC-AC inverter 251, battery 253 and antenna 255 may be included in electrical module 250, within enclosure 140. Enclosure 140, as illustrated is disposed behind back glass 130, proximate to opening 131. In some implementations, enclosure 140 is configured to form a seal, together with back surface 134 of back glass 130, around opening 131.

DC-AC inverter 251 may be configured to convert power output from the PV power generator to an AC power output as described in more detail herein below. Battery 253 may be configured to locally store excess energy, generated by solar panel 100. Antenna 255 may include, for example, a Zigbee antenna or a radio frequency identification (RFID) antenna, accompanied by appropriate radio frequency (RF) circuits. As described in more detail herein below, antenna 255 may be communicatively coupled to an array control center (not shown).

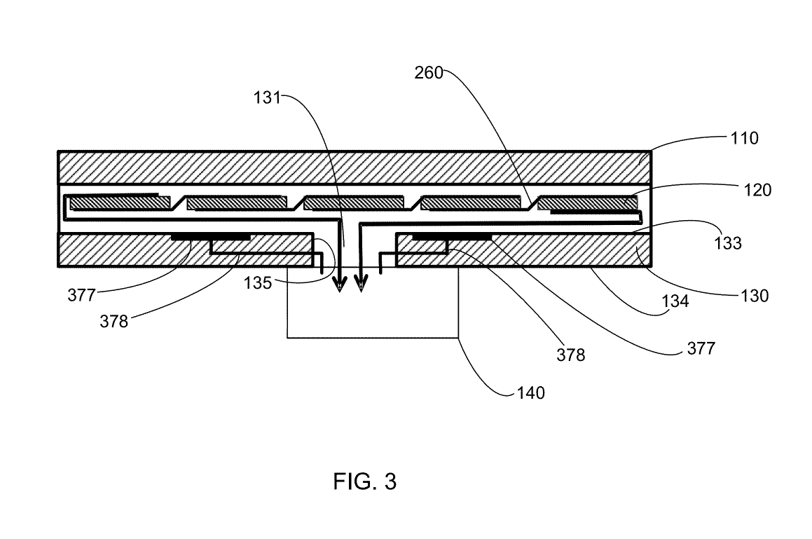

FIG. 3 shows an example of a PV solar panel in accordance with a further implementation. Similarly to the implementation described above with reference to FIG. 2, front glass 110 and back glass 130 encapsulate PV power generating layer 120. In the illustrated implementation, at least some components of one or more of DC-AC inverter 251, battery 253 and antenna 255 are thin form factor electronic components 377. “Thin form factor electronic components” as the term is used herein, means an electronic component having a thickness, of less than approximately 10 millimeters (mm). Advantageously, components having a thickness of less than approximately 5 mm may be selected, so as better fit the components in an available space between front glass 110 and back glass 130.

Advantageously, thin form factor electronic components 377 may be disposed on or proximate to front surface 133 of back glass 130, and be encapsulated together with PV power generating layer 120. In some implementations, thin form factor electronic components 377 may be disposed in regions 132 proximate to opening 131, as illustrated in FIG. 1B. Thin form factor components 377 may include, for example, capacitors, inductors, antenna components and/or battery components, as described in more detail herein below.

Enclosure 140, as illustrated, may be disposed behind back glass 130, proximate to opening 131. Enclosure 140 may include components of DC-AC inverter 251, battery 253 and/or antenna 255 other than thin form factor components 377. The components of DC-AC inverter 251, battery 253 and/or antenna 255 within enclosure 140 may be electrically coupled to thin form factor components 377 by way of electrically conductive paths 378. Components included in enclosure 140 may advantageously include, for example, bulk form components or high heat dissipating components. The bulk form components may include those components having a thickness greater than a gap distance between front glass 110 and back glass 130 or that have lateral dimensions incompatible with the PV solar panel. The heat dissipating components may include metallic components like aluminum radiators and heat sinks.

Electrically conductive paths 378 are illustrated, for clarity, as transiting through back glass 130, but this is not necessarily so. Conductive paths 378 may include, for example, metallic traces disposed on front surface 133 of back glass 130, back surface 134 of back glass 130 and/or circumferential surface 135 of opening 131.

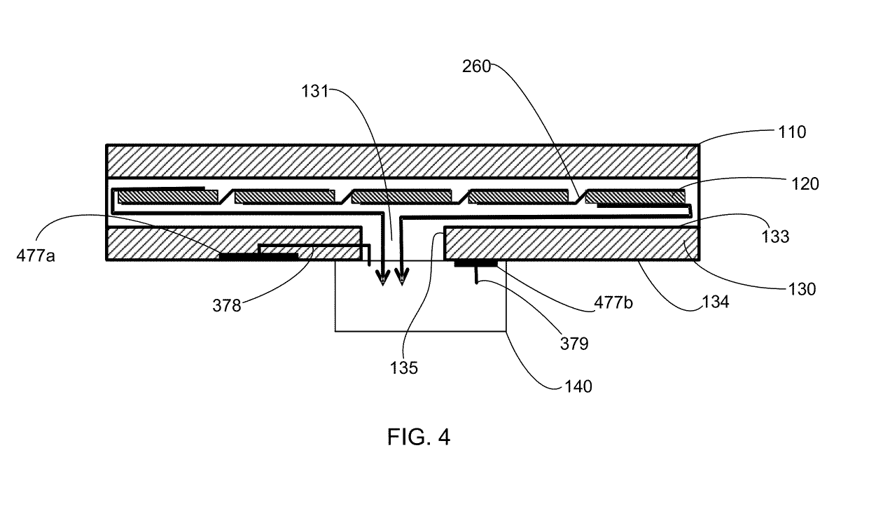

FIG. 4 shows an example of a PV solar panel in accordance with a further implementation. Similarly to the implementations described above with reference to FIG. 2 and FIG. 3, front glass 110 and back glass 130 encapsulate PV power generating layer 120. In the illustrated implementation, at least some components of one or more of DC-AC inverter 251, battery 253 and antenna 255 are thin form factor electronic components 477a and 477b disposed on or proximate to back surface 134 of back glass 130.

In some implementations, thin form factor electronic components 477a and thin form factor electronic components 477b may be disposed in regions 132 proximate to opening 131, as illustrated in FIG. 1B. Thin form factor components 477a and 477b may include, for example, capacitors, inductors, antenna components and/or battery components, as described in more detail herein below.

Enclosure 140, as illustrated, may be disposed behind back glass 130, proximate to opening 131. Enclosure 140 may include components of DC-AC inverter 251, battery 253 and/or antenna 255 other than thin form factor components 477a and 477b. The components of DC-AC inverter 251, battery 253 and/or antenna 255 within enclosure 140 may be electrically connected to thin form factor components 477a and to thin form factor components 477b by, respectively, electrically conductive paths 378 or conductors 379.

In the illustrated implementation, thin form factor electronic components 477a are disposed external to the space enclosed by enclosure 140, and may be electrically coupled to components of DC-AC inverter 251, battery 253 and/or antenna 255 disposed therein by way of electrically conductive paths 378. Electrically conductive paths 378 are illustrated, for clarity, as transiting through back glass 130, but this is not necessarily so. Electrically conductive paths 378 may include, for example, metallic traces disposed on back surface 134 of back glass 130.

In the illustrated implementation, thin form factor electronic components 477b are, advantageously, disposed internal to the space enclosed by enclosure 140, and may be electrically coupled to components of DC-AC inverter 251, battery 253 and/or antenna 255 disposed therein by way of conductors 379.

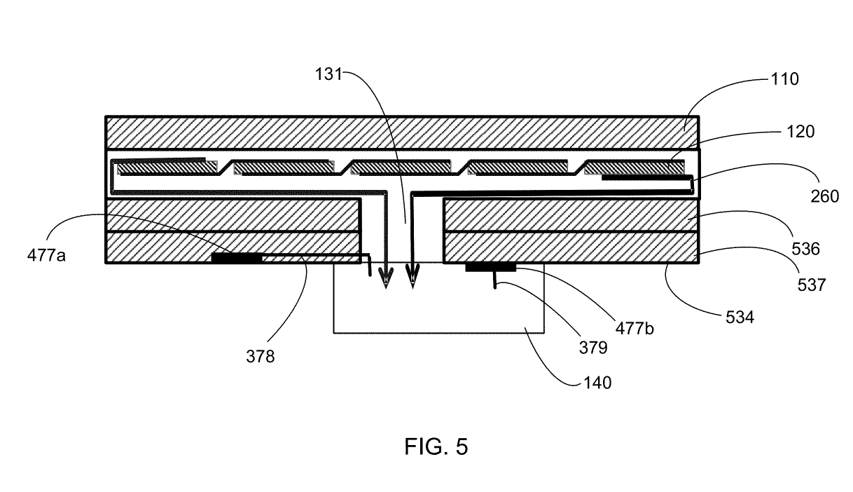

FIG. 5 shows an example of a PV solar panel in accordance with a further implementation. In the illustrated implementation, front glass 110 and first back glass 536 encapsulate PV power generating layer 120. Similarly to the implementation described above with reference to FIG. 4, at least some components of one or more of DC-AC inverter 251, battery 253 and antenna 255 are thin form factor electronic components 477a and 477b.

In the illustrated implementation, thin form factor electronic components 477a and 477b are disposed on or proximate to back surface 534 of second back glass 130. Thin form factor components 477a and 477b may include, for example, capacitors, inductors, antenna or battery components, as described in more detail herein below.

Enclosure 140, as illustrated, may be disposed behind second back glass 537, proximate to opening 131. Enclosure 140 may include components of DC-AC inverter 251, battery 253 and/or antenna 255 other than thin form factor components 477a and 477b. Components of DC-AC inverter 251, battery 253 and/or antenna 255 may be electrically connected to thin form factor components 477a and to thin form factor components 477b by, respectively, electrically conductive paths 378 or conductors 379.

In the illustrated implementation, thin form factor electronic components 477a are disposed external to the space enclosed by enclosure 140, and may be electrically coupled to components of DC-AC inverter 251, battery 253 and/or antenna 255 disposed therein by way of electrically conductive paths 378. Electrically conductive paths 378 are illustrated, for clarity, as transiting through second back glass 537, but this is not necessarily so. Electrically conductive paths 378 may include, for example, metallic traces disposed on back surface 534 of second back glass 537.

In the illustrated implementation, thin form factor electronic components 477b are disposed internal to the space enclosed by enclosure 140, and may be electrically coupled to components of DC-AC inverter 251, battery 253 and/or antenna 255 disposed therein by way of conductors 379.

Second back glass 537 may be secured to first back glass 536 by, for example, an epoxy or other adhesive. In an implementation, first back glass 536 is a back glass of a conventional solar panel. A benefit of such an implementation is that an existing, conventional solar panel may be readily upgraded or retrofitted.

It will be understood that the arrangements described hereinabove represent example implementations, and that numerous variations thereof are within the contemplation of the present inventors. For example, referring still to FIG. 5, one or both of thin form factor electronic components 477a and thin form factor electronic components 477b may be disposed proximate to a front surface second back glass 537. Moreover, although the illustrated implementations provide that thin form factor electronic components are disposed in two regions 132, a single region 132 or more than two regions 132 may be contemplated.

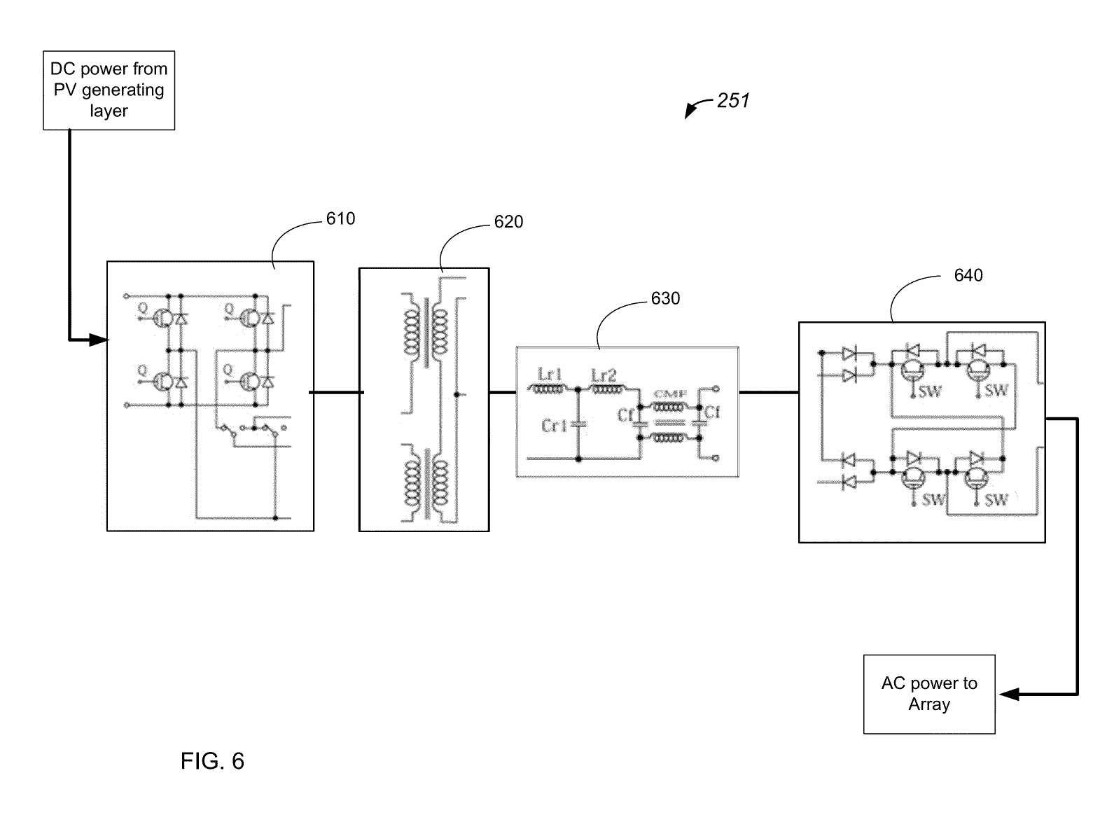

FIG. 6 shows a block diagram of a DC-AC inverter. The DC-AC inverter receives DC current generated by the solar panel, and oscillates the current into AC power synchronized to an AC input signal In the illustrated implementation, DC-AC inverter 251 includes switching arrangement 610, power transformer 620, rectifier/switch arrangement 630, and filter/resonator arrangement 640. In the illustrated implementation, switching arrangement 610 includes a full bridge switching circuit, and filter/resonator arrangement 640 includes a low pass filter. It will be understood that, whereas FIG. 6 depicts specific electrical circuits for each of switching arrangement 610, transformer 620, rectifier/switch arrangement 630, and filter/resonator arrangement 640, these are provided only as examples, and other circuits are within the contemplation of the present inventors.

As indicated above, the present inventors have appreciated that DC-AC inverter 251 may include at least some thin form factor electronic components 377 which may advantageously be disposed proximate to a surface of, for example, back glass 130. The thin form factor electronic components 377 may include passive devices configured in a thin, planar form factor so as to have an inconsequential impact on an effective thickness of back glass 130.

In some implementations, moreover, back glass 130 is configured as a substrate upon which thin form factor electronic components 377 may be integrated. For example, back glass 130 may be used as a substrate for a growing large-area dielectric capacitor, and may conveniently permit deposition of thin form factor inductors as described in more detail herein below. Advantageously, at least some thin form factor electronic components 377 may be configured as microelectromechanical systems (MEMS) devices that include structures having sizes ranging from about one micron to hundreds of microns.

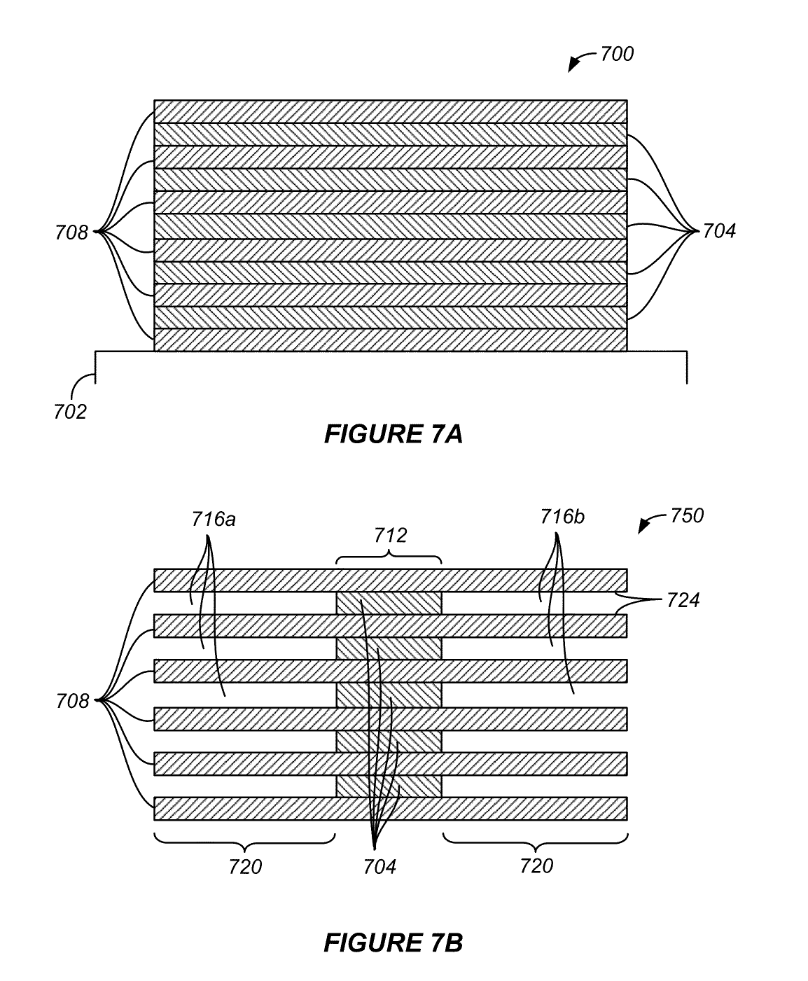

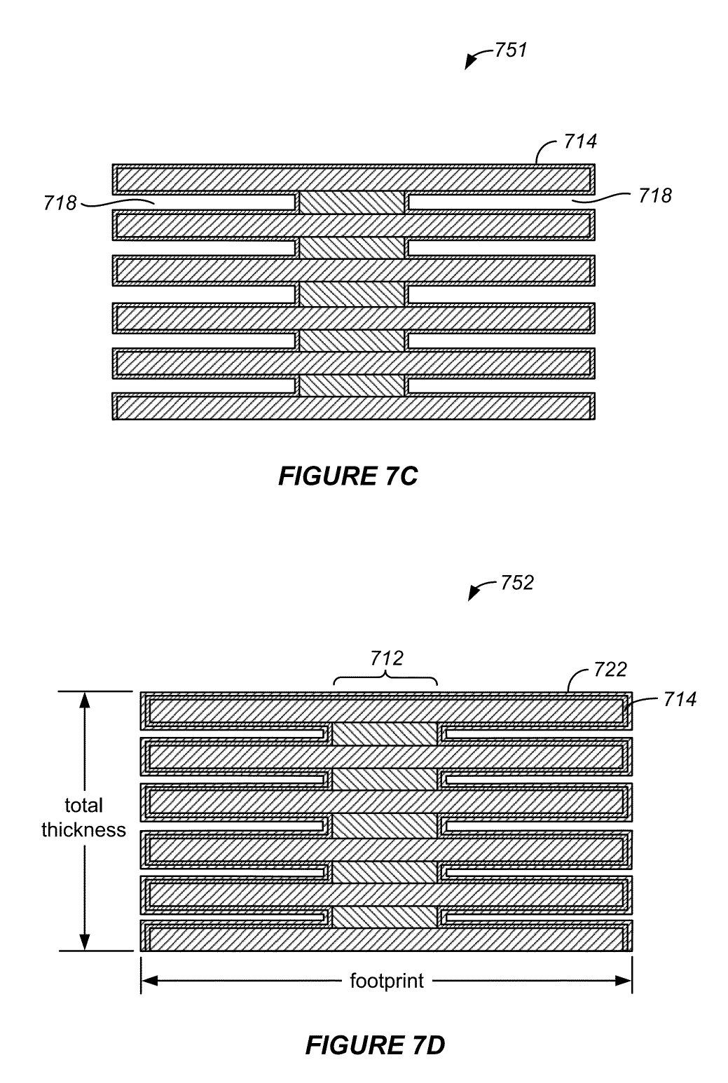

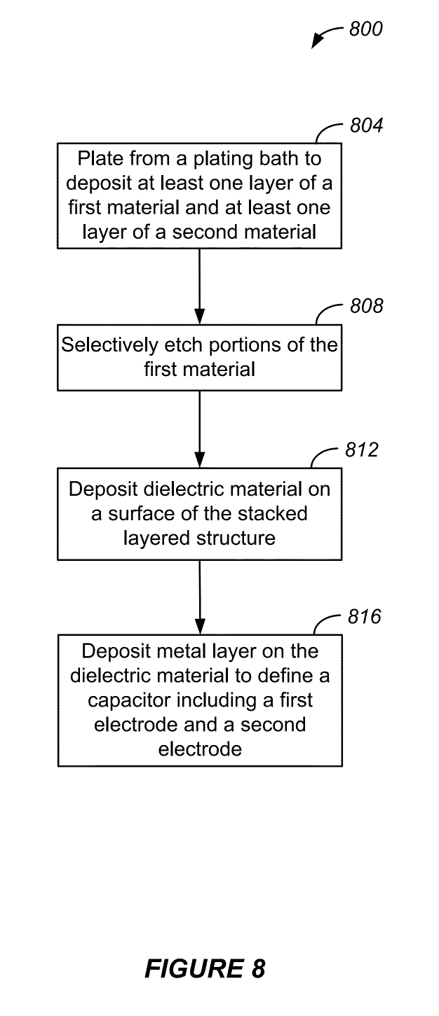

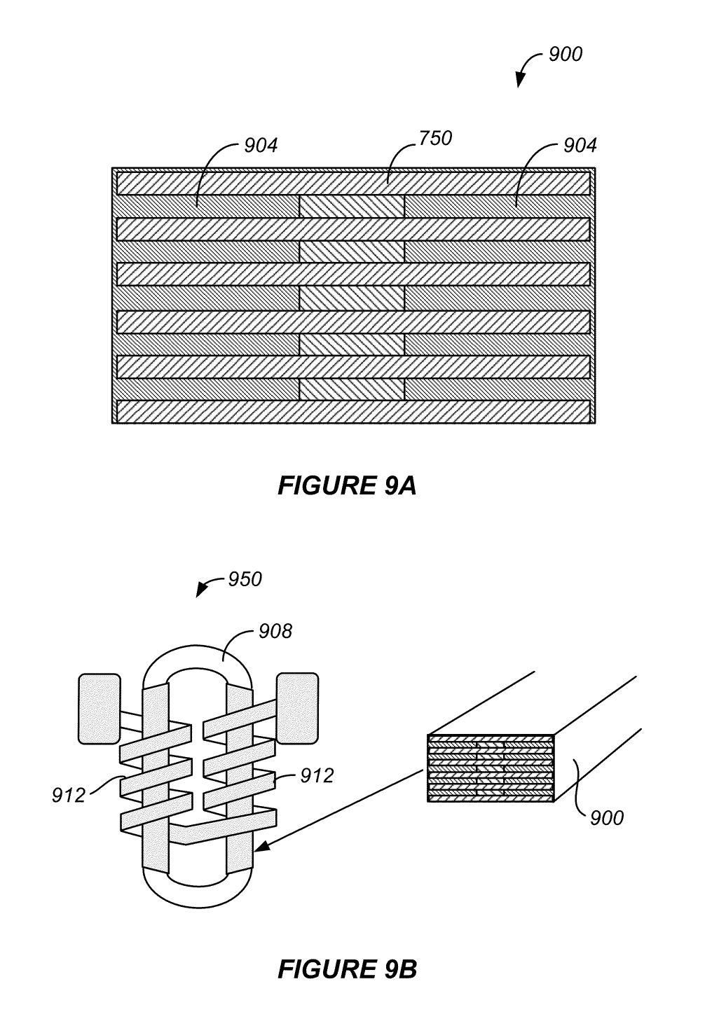

FIG. 7D shows an example of a side view of a capacitor formed from a stacked layered structure configured as a capacitor, whereas FIGS. 7A, 7B, and 7C show, respectively, examples of a first, second and third intermediate result of a process to form such a capacitor from a stacked layered structure. Such a capacitor can be fabricated on back glass 130 of PV solar panel 100 in some implementations. Further, such a capacitor can be used to implement some of the components of the DC-AC inverter 251. In the illustrated implementation, capacitor 752 is a MEMS device including a stacked structure. Advantageously, capacitor 752 may be fabricated in a batch process with a reduced number of lithography, plating and etching process operations to keep the fabrication cost low. Also, the stacked structure may be fabricated on a substrate such as glass and readily integrated with other various components, circuits, and devices on or off the substrate to reduce costs. Unique electro-deposition properties of a first metal such as copper with a second metal such as nickel or some combination of nickel, cobalt, and/or iron, facilitate plating and selective wet etching of the stacked layered structure in a reproducible manner. Atomic layer deposition (ALD) may be used to deposit conformal thin dielectric and metal layers. A high dielectric constant and a thin gap between the electrodes may be achieved with thin, continuous conformal dielectric deposition.

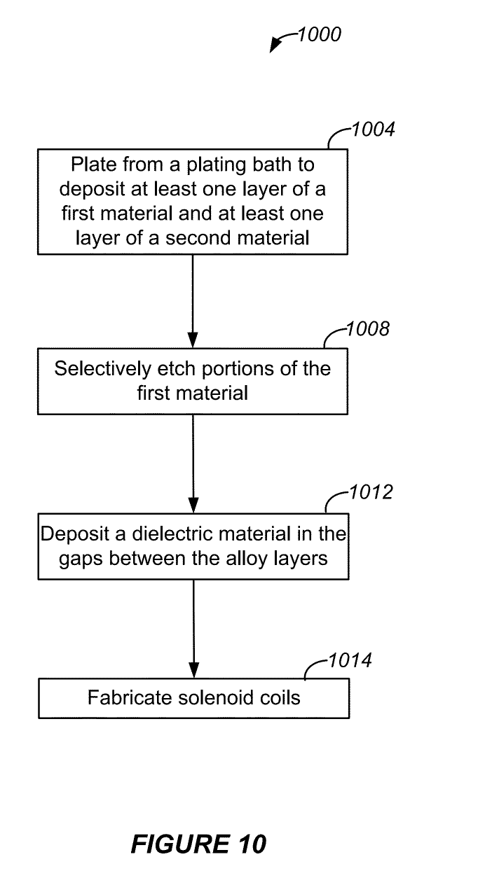

FIG. 8 shows an example of a flow diagram illustrating a process for forming a capacitor from a stacked layered structure. FIG. 8 may be better understood by referring to FIGS. 7A, 7B, and 7C which show, respectively, examples of a first, second and third intermediate result of a process to form a capacitor from a stacked layered structure.

In FIG. 8, process 800 begins in block 804, with plating from a plating bath to deposit at least one layer of a first material and at least one layer of a second material. In some implementations, the first material is a first metal, and the second material is an alloy including the first metal and a second metal. The layers of metal are formed in a stack 700 on a substrate 702, as shown in FIG. 7A. It will be understood that back glass 130 may be configured to function as substrate 702. In some implementations, stack 700 may be formed on a surface of substrate 702 from a plating bath that includes a relatively low concentration of the first metal with the second metal. For example, the first metal can be copper (Cu). The second metal can be nickel (Ni), cobalt (Co), iron (Fe), or other metals. A plating current can be modulated to deposit alternate layers 704 and 708 of the first metal and an alloy that includes the first metal and the second metal. For example, layers 704 may contain nearly exclusively copper and layers 708 may contain nearly exclusively an alloy of copper and one or more of Ni, Co, Fe, or other metals. Layers 704 and 708 may be formed in a single plating operation by modulating current as a function of time to plate a layer of pure or nearly pure first metal 704 at a lower current density, then plate a layer of alloy 708 at a relatively higher current density. In this example, at the higher current density, the first metal in the plating bath is consumed locally so an alloy of the first metal and the second metal is plated. The current density can be varied over a designated time to repeat these two operations and deposit a desired number of alternate layers. As illustrated, the plating operation may begin with a relatively higher current density and hence layer 708 of the alloy is plated first on substrate 702, followed by a lower current density to plate the layer 704 of the first metal, and so forth. By way of example, 100 nm thick Cu layers can be interspersed with 1000 nm thick NiFeCu layers.

In FIG. 8, following the formation of the stacked layers 700 in block 804, method 800 proceeds to block 808 in which portions of the first metal layers 704 are selectively etched to form gaps 716a and 716b between regions 720 of the alternate layers 708 as shown in FIG. 7B. Portions of the alternate layers 708 in regions 720 extend beyond areas occupied by the remaining portions of the first metal layers 704 to define the gaps 716a and 716b, in this example. The stacked layered structure 750 shown in FIG. 7B, defined by the partial etching of portions of the alternate layers 704, results from block 808. The alternate layers 708 now have exposed surfaces 724 in the gaps 716a and 716b and are supported by the remaining portions of the alternate layers 704. These exposed surfaces 724 significantly add to the overall surface area of the stacked layered structure 750. In the example of FIG. 7B, the remaining portions of the first metal layers 704 are located in a core region 712 of the structure 750. In the illustrated implementation, gaps 716a and 716b are similar in surface area and are situated on respective sides of the core region 212, but this is not necessarily so. The remaining portions of first metal layers 704, as well as portions of the alternate layers 708 in contact with the remaining portions of the first metal layers, can be collectively viewed as a core or post of the stacked layered structure.

Referring again to FIG. 8, the selective etching in block 808 may be performed in a single etching operation, in some implementations. Etchants can be selected that will etch the first metal but not etch the alloy of the first metal and the second metal. For instance, hydrogen peroxide acidic acid or ammonia nickel copper etch can be used to selectively etch pure copper layers. The amount of first metal material removed by the etching is generally determined by etch time. Various dimensions can be created based on the length of time the metal layers are exposed to the etchant.

In block 812, a dielectric material 714 such as alumina may be deposited about a surface of the stacked layered structure 750, resulting in stacked layered structure 751 as shown in FIG. 7C. Various dielectric materials can be used, such as aluminum oxide (Al₂O₃), zirconium oxide (ZrO₂) and tantalum dioxide (Ta₂O₅). The dielectric material 714 can be deposited using atomic layer deposition (ALD). Such a surface-based deposition technique can facilitate coverage of all of the exposed surfaces of the stacked layered structure 751 with a uniform thickness of the deposited dielectric material 714. The thickness may be very small, for instance, on the order of 100 Angstroms. As shown in FIG. 7C, the layer of dielectric material 714 is relatively thin, as layer 714 coats the outer surface of the stacked layered structure 750 while leaving substantial regions 718 of the gaps 716a and 716b. That is, the dielectric material 714 coats the exposed top and bottom surfaces 724 of the alternate layers 708 and side walls of the remaining portions of the first metal layers 704, while the remaining regions 718 of the gaps 716a and 716b are unfilled. These remaining regions 718 can be high aspect ratio lateral cavities, for instance, when ALD or other surface chemistry based technique is used to deposit the dielectric material 714.

Referring again to FIG. 8, method 800 continues to block 816 with the deposition of a conductive layer 722, as shown in FIG. 7D. Conductive layer 722 may include one or more metals such as ruthenium (Ru), platinum (Pt), rhodium (Rh), and/or iridium (Ir). In some implementations, conductive layer 722 also may be deposited using ALD in the regions 718 remaining after deposition of the dielectric material 714. In such implementations, the metal can be any metal that may be deposited using ALD or other surface chemistry based technique. In some other implementations, the conductive layer 722 can be deposited using techniques such as electrodeless plating, also referred to as chemical or auto-catalytic plating. As shown in FIG. 7D, the thin conductive layer 722 coats the surface of the dielectric material 714, while leaving portions of regions 718 unfilled, in this example. In other examples, the regions 718 can be filled with the conductive layer 722.

In FIG. 7D, the resulting capacitor 752 includes a first electrode in the form of the stacked layered structure 250. A second electrode is in the form of the outer conductive layer 722 disposed about the dielectric material 714. The number of layers and total stack thickness are variables that can be increased to increase the surface area of the structure. Increasing the total thickness and/or increasing the number of layers for a given layout footprint results in an increase in the effective transduction surface area of the stacked layered structure. For instance, a 20 micrometer-thick structure would have 4× more layers than a 5 micrometer-thick stack, when layer thickness is constant, and thus more surface area. Also, the thicknesses of one or more individual layers can be engineered to control the surface area of the structure and finely tune the capacitance. Thus, capacitors can be constructed with a wide variety of different capacitance values, depending on the desired implementation. In one example, fifty layers or more of Cu (first metal) interposed with alloy layers of Cu with NiCu (second metal) can be deposited. High aspect ratio metal plating processes can be used to plate structures having total thicknesses in the ranges of 100 to 1000 micrometers or more, enabling further increases in capacitor area per unit footprint.

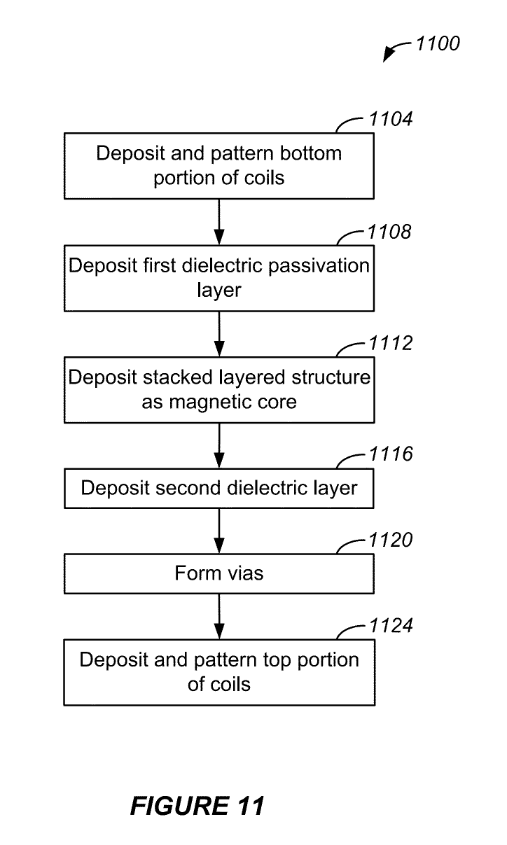

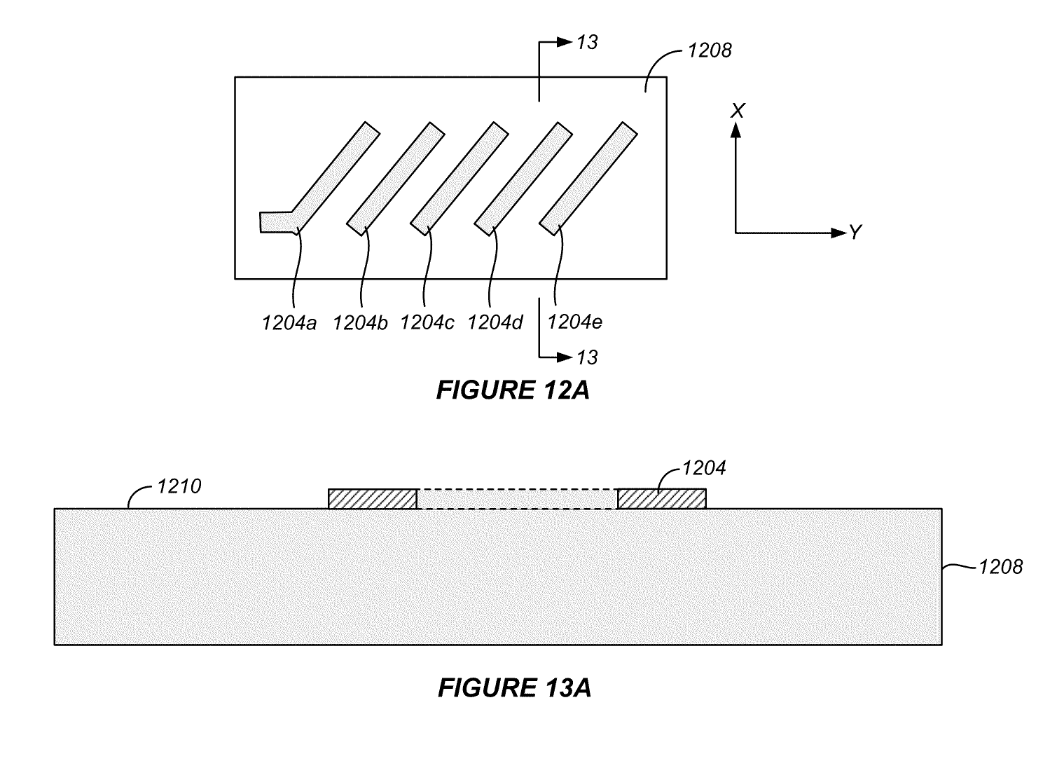

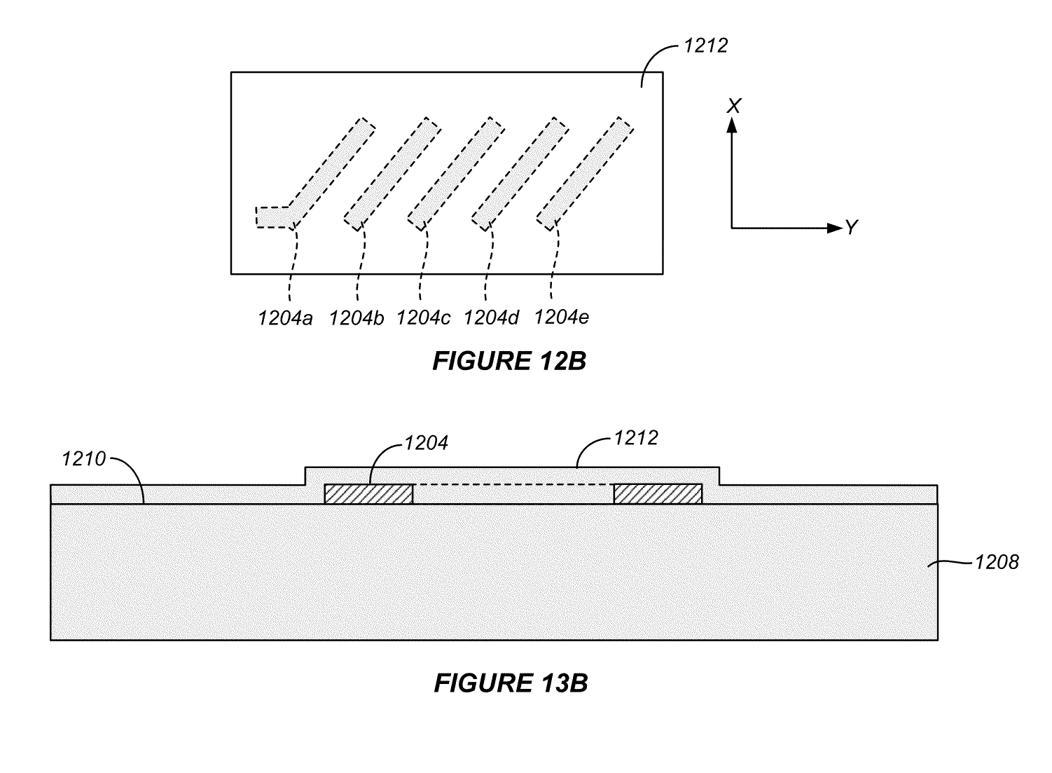

FIG. 10 shows an example of a flow diagram illustrating a method for forming an inductor as a MEMS device including a stacked layered structure. FIG. 10 may be better understood by referring to FIGS. 9A and 9B, which show, respectively, an example of a first intermediate result of a process to form an inductor having a stacked layered structure serving as a magnetic core, and an example of a perspective view of the inductor having a stacked layered structure serving as a magnetic core.

In FIG. 10, method 1000 begins in blocks 1004 and 1008, which are similar to blocks 804 and 808 of FIG. 8 described above. Blocks 1004 and 1008 result in the formation of a stacked layered structure 750 as described above with reference to FIG. 7B. In block 1012, a dielectric material 904 is deposited on the surface of the structure 750, as shown in FIG. 9A. In this example, the dielectric material 904 is deposited in a manner such that the material 904 fills the gaps 716a and 716b (FIG. 7B) on both sides of the core region 712 (FIG. 7B) of structure 750. The resulting structure 900 can serve as a laminated magnetic core 908, as shown in FIG. 9B.

Referring again to FIG. 10, at block 1014, solenoid coils 912 formed of an appropriate metal such as copper may be fabricated by planar induction processes and wrapped around the magnetic core 908 as shown in FIG. 9B to realize the inductor 950.

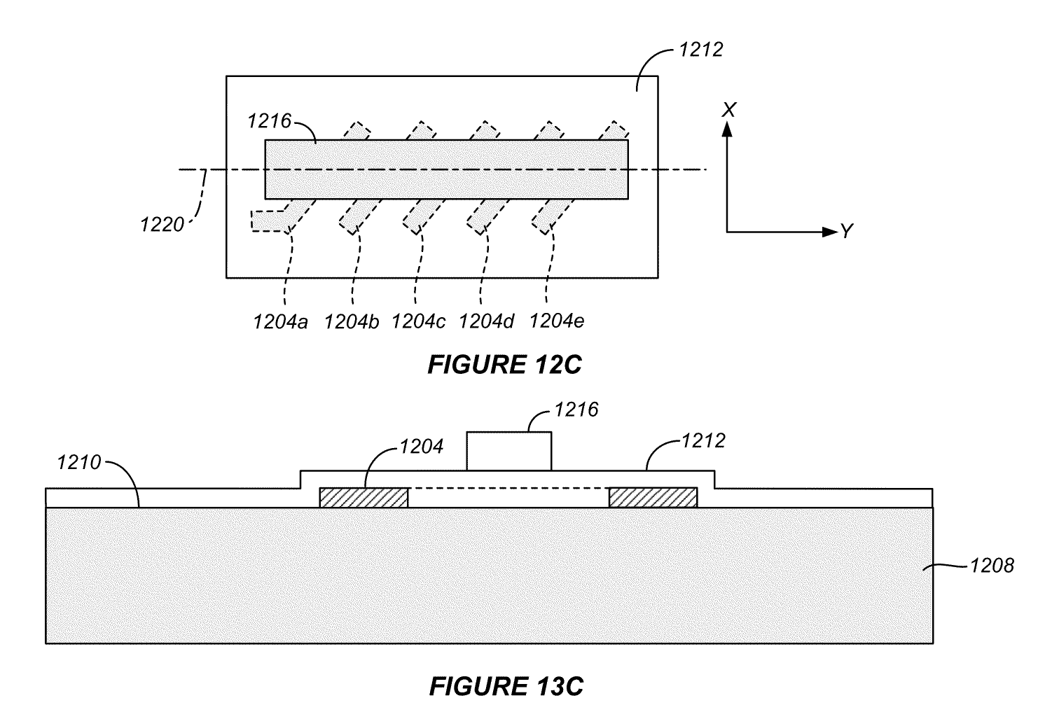

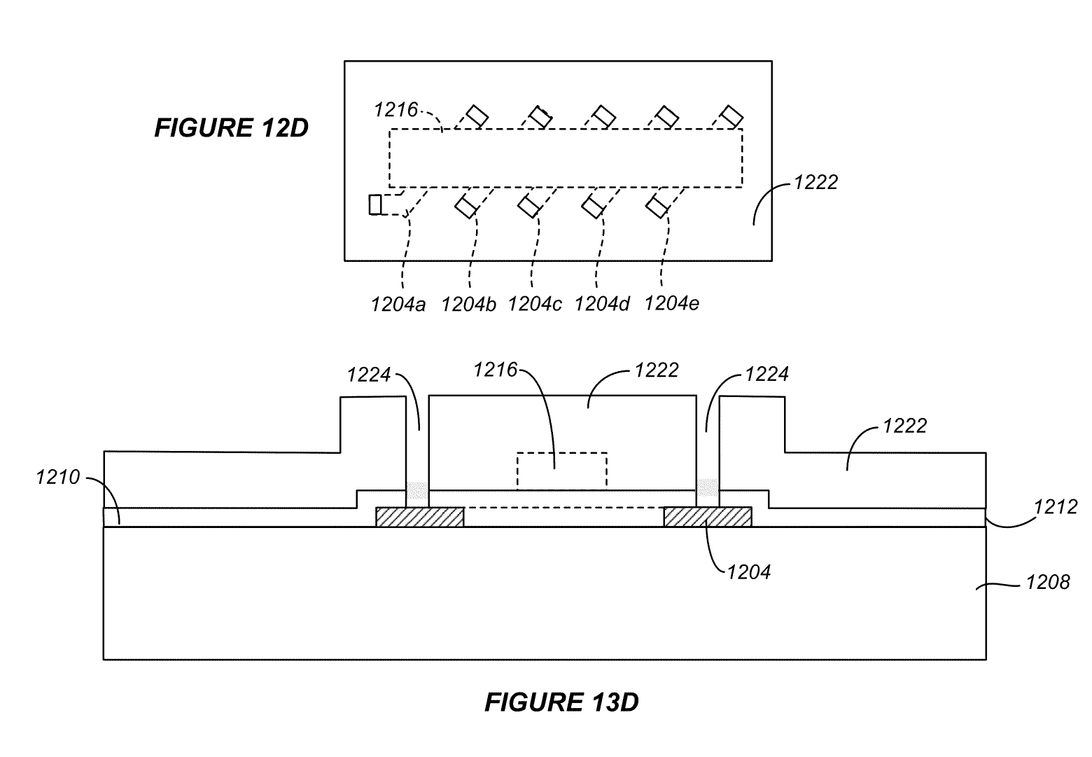

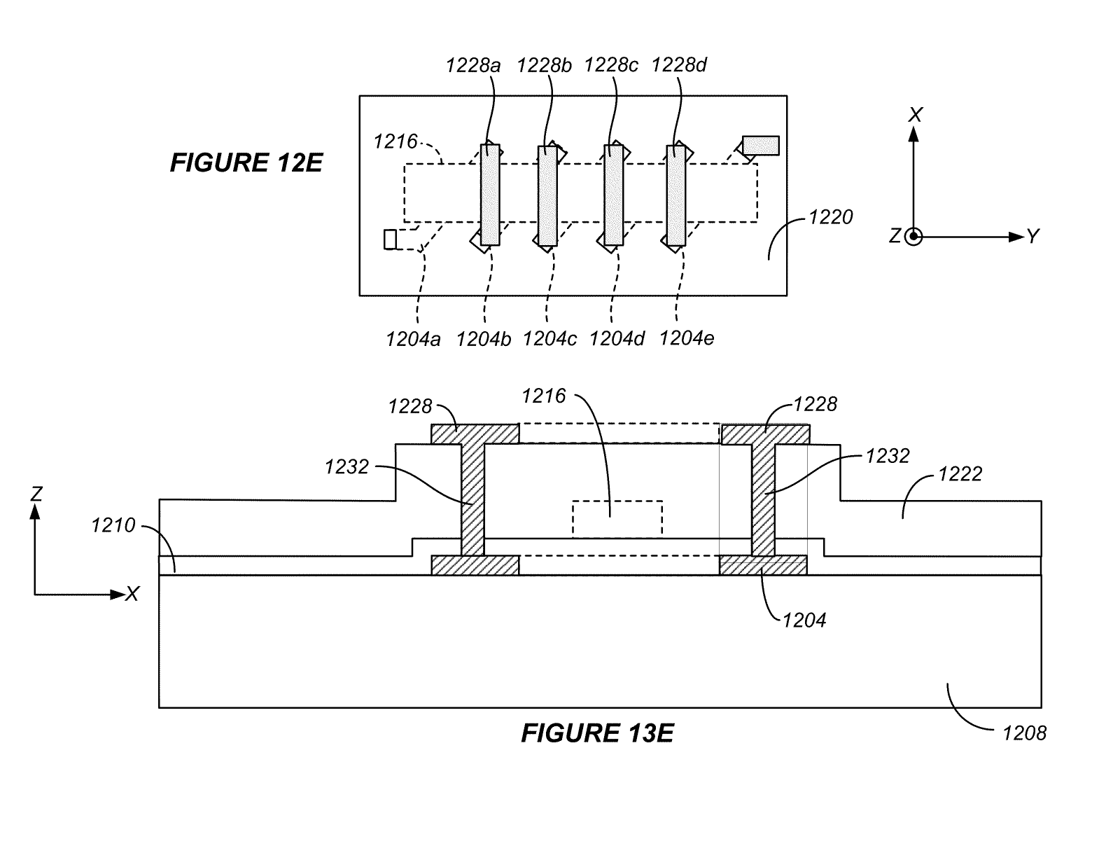

FIG. 11 shows an example of a flow diagram illustrating a method of forming an inductor by depositing coil portions around a stacked layered structure. FIG. 11 is described with reference to FIGS. 12A-12E, which show an example of a top view of an inductor at respective stages of fabrication, and with reference to FIGS. 13A-13E, which show an example of a cross-sectional view along lines 13-13 of FIG. 12A of the inductor of FIGS. 12A-12E at the respective stages of fabrication.

In FIG. 11, the method 1100 begins in block 1104 with depositing and patterning a bottom portion 1204 of metal coils on an insulating substrate 1208 such as glass, as shown in FIGS. 12A and 13A. It will be understood that back glass 130 may be configured to function as insulating substrate 1208. In this example, bottom portion 1204 includes coil segments 1204a-1204e physically and electrically disconnected from one another and diagonally oriented with respect to X and Y axes, for purposes of illustration, on a surface of the substrate 1208 as shown in FIG. 12A. Following block 1104, method 1100 transitions to block 1108, in which a first dielectric passivation layer 1212 is deposited over the bottom portion 1204 of coils and exposed regions 1210 of the surface of the substrate 1208, as shown in FIGS. 12B and 13B.

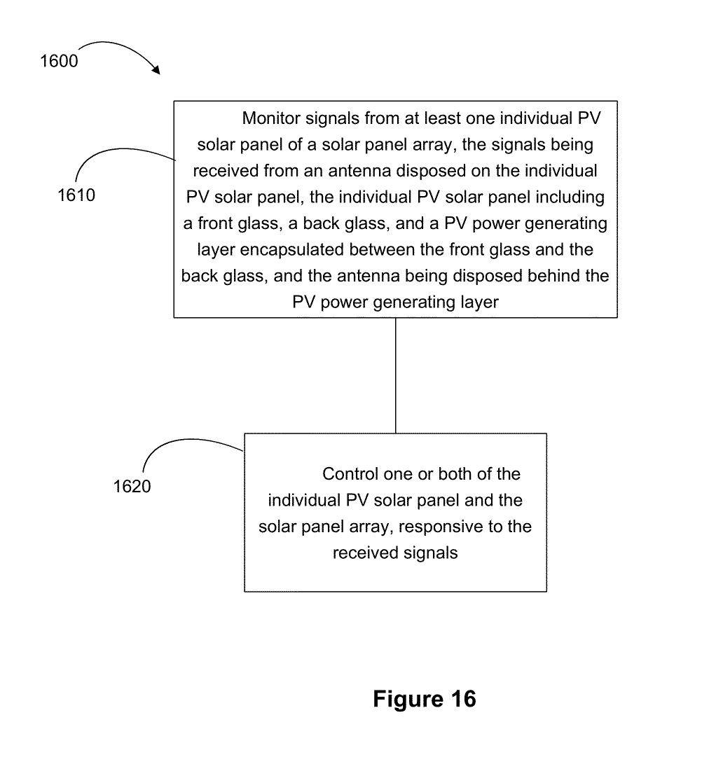

In FIG. 11, in block 1112, a stacked layered structure (such as stacked layered structure 900 as described above with reference to FIG. 9A, and FIG. 9B) serving as a laminated magnetic core 1216 is deposited on the first dielectric layer 1212, as shown in FIGS. 12C and 13C. The laminated magnetic core 1216 has a longitudinal axis 1220 oriented along the Y axis, such that the magnetic core 1216 overlays portions of the coil segments 1204a-1204e, as shown in FIG. 12C. Following block 1112, method 1100 transitions to block 1116, in which a second dielectric layer 1222 is deposited over the magnetic core 1216 and exposed surface regions of the first dielectric layer 1212, as shown in FIGS. 16D and 17D. In block 1120, vias 1224 are formed, for instance, by etching, to access the bottom portion 1204 of coils.

In FIG. 11, in block 1124, a top portion 1228 of coils is deposited and patterned, including segments 1228a-1228d, as shown in FIGS. 12E and 13E. In this example, segments 1228a-1228d are substantially oriented along the X axis, as shown in FIG. 12E, and have connecting members 1232 substantially oriented along a Z axis, as shown in FIG. 13E, extending through the vias 1224 to connect the top segments 1228a-1228d with respective pairs of bottom segments, as shown in FIGS. 12E and 13E. For example, top segment 1228a electrically couples bottom segments 1204a and 1204b (of FIG. 12A) to each other, top segment 1228b couples bottom segments 1204b and 1204c to each other, and so forth, by virtue of connecting members 1232.

Although the foregoing description relates to fabrication of capacitors and inductors as MEMS devices on back glass 130, in some implementations, other components may be integrated onto a surface of back glass 130. For example, a thin form factor rechargeable battery, such as a Li-ion battery may be contemplated. In some implementations, such a battery may have a thickness of less than one millimeter. The battery may be configured to locally store excess energy generated by the solar panel 100. In addition, solar panel 100 may include performance meters and environmental sensors, components, at least, of which may be integrated onto a surface of, for example, back glass 130. For example, solar panel 100 may include output current and voltage sensors, a sunlight photodetector, a temperature sensor, a battery state of charge detector, and/or a MEMS-based wind velocity sensor, such as an ultrasonic or piezoelectric air flow sensor.

In some implementations, one or more antennas may be provided, including, for example, a Zigbee antenna or an RFID antenna, accompanied by appropriate RF circuits, components, at least of which may be integrated onto a surface of, for example, back glass 130. The antennas may be communicatively coupled to an array control center, for example.

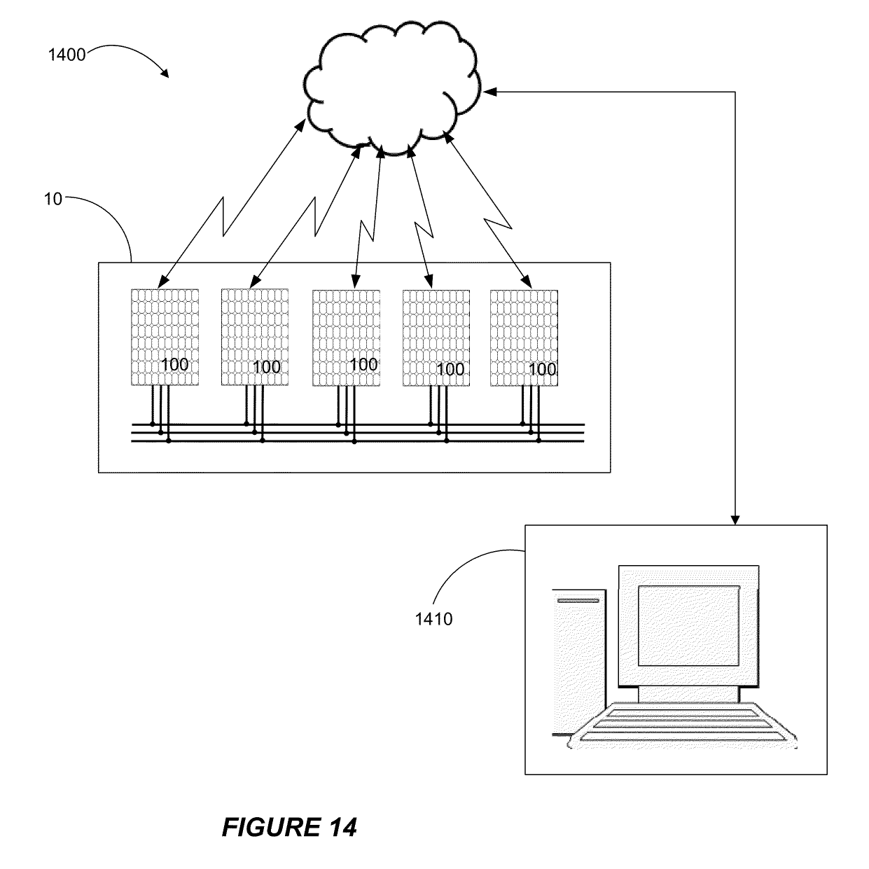

FIG. 14 shows an example of a system including an array of photovoltaic (PV) solar panels with functional back glasses. System 1400 includes solar panel array 10. At least some of solar panels 100 included in solar panel array 10 feature functional back glasses as described hereinabove, and may be configured to be communicatively coupled to an array control center 1410. For example, sensor outputs from each solar panel 100 may be received by array control center 1410, which may be remotely located from solar panel array 10.

In some implementations, a logic control circuit may be configured to provide for panel identification, in-situ monitoring, and diagnosis. In some implementations, a wireless transceiver may be provided that automatically sends an error signal to the array control center 1410 in the event of an anomaly. In response to a command from the array control center 1410, or, in some implementations, autonomously, the panel current output may be cut off in the event of an anomaly. Responsive to the received signals, array control center 1410 may send commands to individual solar panels 100 to, e.g., cut off panel output current in the event of a malfunction. Thus, an individual solar panel 100 may be configured to be monitored and controlled by array control center 1410, independent of any other solar panel in the solar panel array.

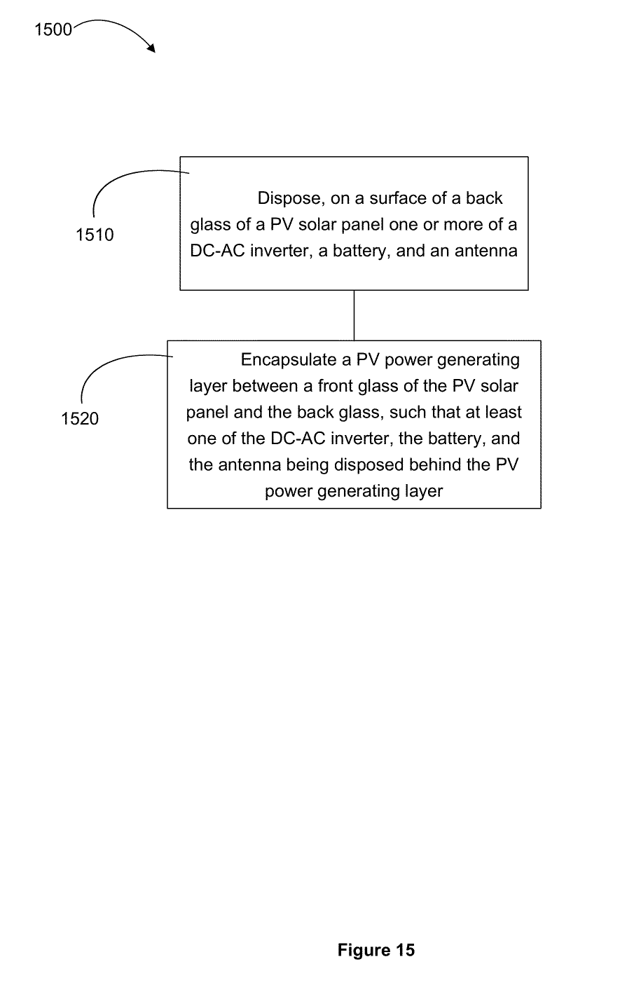

FIG. 15 shows an example of a flow diagram illustrating a method for fabricating a PV solar panel in accordance with an implementation. Method 1500 may be initiated at block 1510 wherein one or more of a DC-AC inverter, a battery, and an antenna may be disposed, on a surface of a back glass of a PV solar panel. In an implementation, at least some components of the DC-AC inverter, the battery, and the antenna are disposed on a front surface of the back glass, and encapsulated between the back glass and a PV power generating layer. Advantageously, where the DC-AC inverter includes at least one capacitor and at least one inductor, one or more of the capacitor and the inductor are fabricated on the back glass.

At block 1520, the PV power generating layer may be encapsulated between a front glass of the PV solar panel and the back glass, at least one of the DC-AC inverter, the battery, and the antenna being disposed behind the PV power generating layer. Details of some implementations of the PV solar panel have been described above.

FIG. 16 shows a flow diagram illustrating an example of a method for operating an array of PV solar panels in accordance with an implementation. Method 1600 may be initiated at block 1610 wherein signals from at least one individual PV solar panel of a solar panel array may be monitored. The signals may be representative of a performance parameter of the individual PV solar panel, or of an output of an environmental sensor, for example. The signals may be received by, for example, an array control center. In an implementation, the signals may be transmitted by an antenna disposed on the individual PV solar panel, where the individual PV solar panel includes a front glass, a back glass, and a PV power generating layer encapsulated between the front glass and the back glass, and the antenna is disposed behind the PV power generating layer.

At block 1620 the individual PV solar panel and/or the solar panel array may be controlled, responsive to the received signals. For example, the solar panel current output may be cut off in the event of an anomaly. Advantageously, this may be accomplished from a remote array control center. In an implementation, the control center is configured to monitor and control at least some individual PV solar panels in the solar panel array, independent of any other solar panel in the solar panel array.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above also may be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other possibilities or implementations.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

1. A photovoltaic (PV) solar panel comprising:
a front glass;
a back glass;
a PV power generating layer encapsulated between the front glass and the back glass, and configured to convert ambient electromagnetic energy, received through the front glass, to a direct current (DC) power output; and
at least one electronic component disposed behind the PV power generating layer, the at least one electronic component including one or more of a direct current to alternating current (DC-AC) inverter configured to convert the DC power output from the PV power generating layer to an alternating current (AC) power output, a battery, and an antenna.

2. The solar panel of claim 1, wherein the at least one component is disposed on a surface of the back glass.

3. The solar panel of claim 1, wherein the at least one component is disposed on a front surface of the back glass, and encapsulated between the back glass and the PV power generator.

4. The solar panel of claim 1, wherein the at least one component is disposed behind the back glass.

5. The solar panel of claim 1, wherein:
the DC-AC inverter includes a capacitor and an inductor; and
one or both of the capacitor and the inductor are fabricated on the back glass.

6. The solar panel of claim 5, wherein the back glass is configured as a substrate for growing the capacitor and for deposition of the inductor.

7. The solar panel of claim 1, wherein the DC-AC inverter includes a switching arrangement, a power transformer, a rectifier, a low pass filter and a resonator circuit.

8. The solar panel of claim 1, wherein the at least one component includes the battery, the battery being a thin form factor rechargeable battery having a thickness of less than approximately 10 millimeters.

9. The solar panel of claim 1, wherein the at least one component includes the antenna and a radio frequency (RF) circuit, the antenna being a Zigbee or radio frequency identification (RFID) antenna.

10. The solar panel of claim 1, wherein the solar panel includes the DC-AC inverter, a logic control circuit, the antenna, and an RF circuit.

11. The solar panel of claim 10, wherein each of the DC-AC inverter, the logic control circuit, the battery, the antenna, and the RF circuit are integrated as a module disposed behind the back glass.

12. The solar panel of claim 10, wherein the solar panel includes one or more of: a photodetector, a temperature sensor, and wind velocity sensor.

13. The solar panel of claim 12, wherein the antenna is communicatively coupled to an array control center, transmits output data received from the logic control circuit or the at least one sensor to the array control center.

14. The solar panel of claim 13 wherein the antenna receives control signals from the array control center.

15. A solar panel array comprising:
a plurality of solar panels, connected in a string, each solar panel configured to produce output power, and each solar panel including:
a front glass;
a backglass;
a photovoltaic (PV) power generating layer encapsulated between the front glass and the back glass; and
a direct current to alternating current (DC-AC) inverter disposed behind a back surface of the PV power generating layer, the DC-AC inverter configured to convert DC power output by the PV power generating layer into alternating current (AC) power.

16. The solar panel array of claim 15, wherein the plurality of solar panels is connected to the string in parallel.

17. The solar panel array of claim 15, wherein at least one solar panel includes an antenna that is communicatively coupled to an array control center.

18. The solar panel array of claim 17, wherein the at least one of the plurality of solar panels is configured to be monitored and controlled by the array control center, independent of any other solar panel in the plurality of solar panels.

19. A photovoltaic (PV) solar panel comprising:
a front glass;
a first back glass;
a second back glass; and
a PV power generating layer encapsulated between the front glass and the first back glass; wherein:
the second back glass is disposed behind the first back glass and includes one or more of: a direct current to alternating current (DC-AC) inverter, a battery, and an antenna.

20. The solar panel of claim 19, wherein the second back glass is laminated to the back surface of the first back glass.

21. An apparatus comprising:
means for generating photovoltaic (PV) power, encapsulated between a front glass and a back glass of a PV solar panel, and having a back surface, the PV solar panel defining a planar area; and
means, disposed behind the back surface and proximate to the center of the planar area, for converting direct current (DC) power to alternating current (AC) power.

22. The apparatus of claim 21, wherein the means for converting DC power to AC power is disposed on a surface of the back glass.

23. The apparatus of claim 21, wherein the wherein the means for converting DC power to AC power includes at least one capacitor and at least one inductor, and wherein one or more of the capacitor and the inductor are fabricated on the back glass.

24. A method for fabricating a photovoltaic (PV) solar panel, comprising:
disposing, on a surface of a back glass of the PV solar panel, one or more of: a direct current to alternating current (DC-AC) inverter, a battery, and an antenna; and
encapsulating a photovoltaic power generating layer between a front glass of the PV solar panel and the back glass; wherein
the at least one component is disposed behind the PV power generating layer.

25. The method of claim 24, wherein the at least one component is disposed on a front surface of the back glass, and encapsulated between the back glass and the PV power generating layer.

26. The method of claim 24, wherein the DC-AC inverter includes at least one capacitor and at least one inductor, and one or more of the capacitor and the inductor are fabricated on the back glass.

27. A method comprising:
monitoring signals from at least one individual photovoltaic (PV) solar panel of a solar panel array, the signals being received from an antenna disposed on the individual PV solar panel; and
controlling one or both of the individual PV solar panel and the solar panel array, responsive to the received signals; wherein
the individual PV solar panel includes a front glass, a back glass, and a PV power generating layer encapsulated between the front glass and the back glass; and
the antenna is disposed behind the PV power generating layer.

28. The method of claim 27, wherein the solar panel array includes a plurality of solar panels, and the output power of each solar panel includes alternating current (AC) power.

29. The method of claim 28, wherein the controlling one or both of the individual PV solar panel and the solar panel array is performed at an array control center remote from the solar panel array, independent of any other solar panel in the solar panel array.
